(19) United States
(12) Patent Application Publication
(10) Pub. No.: US 2010/0216278 A1
(43) Pub. Date: Aug. 26, 2010

(54) Method for making multi-cystalline film of solar cell

(75) Inventors: Tsun-Neng Yang, Taipei City (TW); Shan-Ming Lan, Taoyuan County (TW); Chin-Chen Chiang, Taoyuan County (TW); Wei-Yang Ma, Banqiao City (TW); Chien-Te Ku, Pingzhen City (TW); Yu-Hsiang Huang, Pingzhen City (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 11/976,916

(22) Filed: Oct. 29, 2007

(51) Int. Cl. H01L 21/20

(52) U.S. Cl. 438/97; 257/E21.09

(57) ABSTRACT

A method is disclosed for making a multi-crystalline silicon film of a solar cell. In the method, a titanium-based film is coated on a ceramic substrate. A back surface field layer is coated on the titanium-based film via providing dichlorosilane and diborane in an atmospheric pressure chemical vapor deposition process at a first temperature. A light-soaking layer is coated on the back surface field layer via providing more dichlorosilane and diborane in the atmospheric pressure chemical vapor deposition process at a second temperature higher than the first temperature.

### BACKGROUND OF INVENTION

1. Field of Invention

The present invention relates to a solar cell and, more particularly, to a method for making a multi-crystalline silicon film in a solar cell.

2. Related Prior Art

Most silicon-based solar cells are made in low-temperature processes based on plasma-enhanced chemical vapor deposition (“PECVD”). An amorphous silicon or multi-crystalline silicon film is coated on a glass, aluminum, silicon, stainless steel or plastic substrate. A back contact is made of aluminum, gold, silver or transparent conductive oxide such as indium-tin oxide (“ITO”) and zinc oxide.

The primary advantage of the low-temperature processes is the wide variety of materials that can be used to make the substrates. However, they suffer drawbacks such as defective silicon films, low photoelectrical conversion efficiencies and low light-soaking stability.

In the PECVD, while coating the microcrystalline silicon film, a silicon material is highly diluted in hydrogen. For example, [H₂]/[SiH₄]>15. That is, the concentration or flow rate of H₂ is more than 15 times as high as that of SiH₄. The problems with the PECVD are a low growth rate of the film, a long process and a high cost.

Regarding the making of the poly-silicon solar cells, there are various techniques such as solid phase crystallization (“SPC”) and aluminum-induced crystallization (“AIC”). The SPC is based on the PECVD. An amorphous silicon film is deposited, intensively heated and annealed at a high temperature. Thus, a poly-silicon film with a grain size of 1 to 2 micrometers is made.

In the AIC as shown in FIGS. 5 through 9, an aluminum film 32 is coated on a substrate 31. An amorphous silicon film 33 is coated on the aluminum film 32 based on the PECVD and annealed at a temperature of about 575 degrees Celsius for a long time to form a seeding layer 34. Then, it is subjected to an epitaxial process such as the PECVD or an electron cyclotron resonance chemical deposition (“ECR-CVD”) to make a poly-silicon film 35. The AIC however involves many steps and takes a long time. The resultant grain size is about 0.1 to 10 micrometers.

As discussed above, regarding the conventional methods for making poly-silicon film solar cells in the low-temperature processes based on the PECVD, there are many defects in the silicon films, the photoelectrical conversion efficiencies are low, the light soaking stabilities low, the growth rates of the films low, the processes long, and the costs high. Concerning the method for making poly-silicon film solar cells based on the AIC, the processes are long for including many steps and therefore expensive.

The present invention is therefore intended to obviate or at least alleviate the problems encountered in prior art.

### SUMMARY OF INVENTION

It is an objective of the present invention is to provide an efficient method for making a multi-crystalline silicon film of a solar cell.

It is another objective of the present invention to provide a method for providing a quality multi-crystalline silicon film of a solar cell.

It is another objective of the present invention to provide a method for making a multi-crystalline silicon film that can be used to make a solar cell that exhibits a high photoelectrical conversion efficiency and stable light-soaking.

To achieve the fore-going objectives, in a method, a titanium-based film is coated on a ceramic substrate. A back surface field layer is coated on the titanium-based film via providing dichlorosilane and diborane in an atmospheric pressure chemical vapor deposition process at a first temperature. A light-soaking layer is coated on the back surface field layer via providing more dichlorosilane and diborane in the atmospheric pressure chemical vapor deposition process at a second temperature higher than the first temperature.

Other objectives, advantages and features of the present invention will become apparent from the following description referring to the attached drawings.

### BRIEF DESCRIPTION OF DRAWINGS

The present invention will be described via detailed illustration of the preferred embodiment referring to the drawings.

FIG. 1 is a flowchart of a method for making a multi-crystalline silicon film of a solar cell according to the preferred embodiment of the present invention.

FIG. 2 is a side view of a ceramic substrate coated with a back contact in the method shown in FIG. 1.

FIG. 3 is a side view of a back surface field layer coated on the back contact shown in FIG. 2.

FIG. 4 is a side view of a light-soaking layer coated on the back surface field layer shown in FIG. 3.

FIG. 5 is a side view of a substrate used in a conventional method for making a multi-crystalline silicon film.

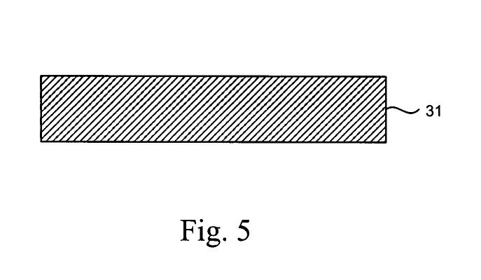

FIG. 6 is a side view of an aluminum film coated on the substrate shown in FIG. 5.

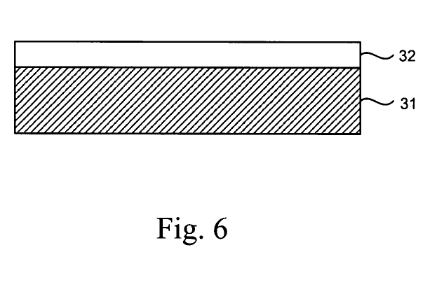

FIG. 7 is a side view of an amorphous silicon film coated on the aluminum film shown in FIG. 6.

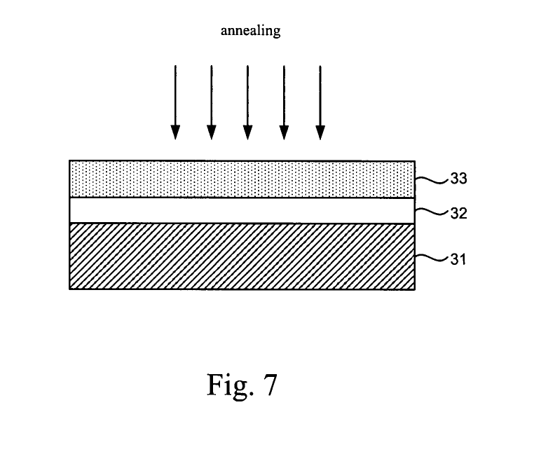

FIG. 8 is a side view of the substrate coated with a seed layer converted from the amorphous silicon film and the aluminum film shown in FIG. 7.

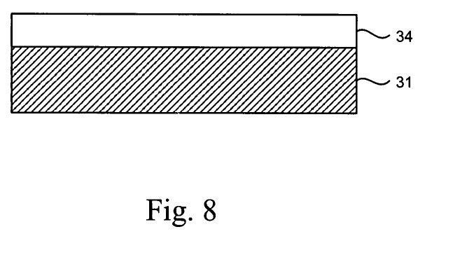

FIG. 9 is a side view of a multi-crystalline silicon film coated on the seed layer shown in FIG. 6.

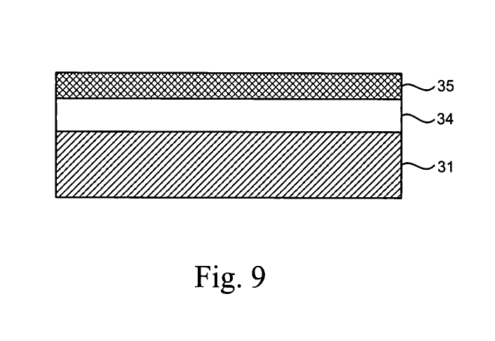

### DETAILED DESCRIPTION OF PREFERRED EMBODIMENT

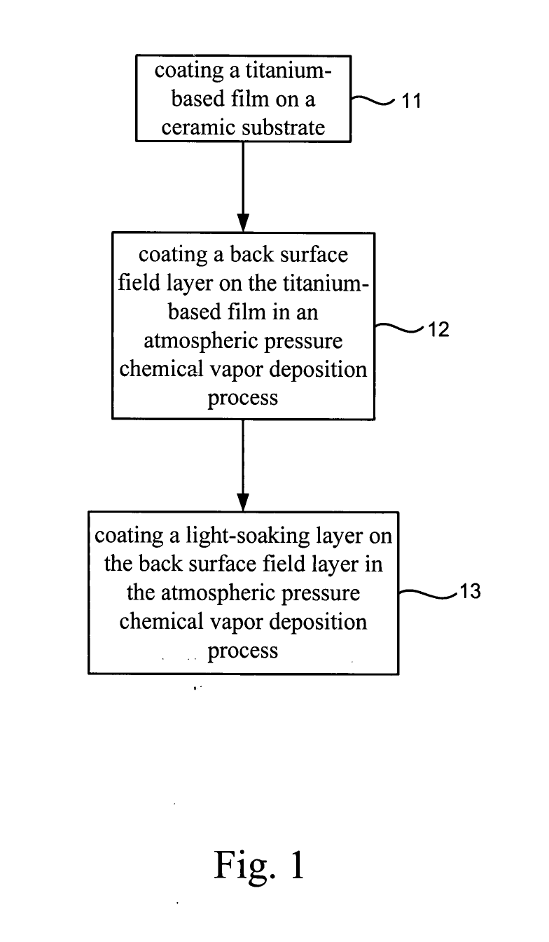

Referring to FIG. 1, shown is a method for making a multi-crystalline silicon film of a solar cell according to the preferred embodiment of the present invention.

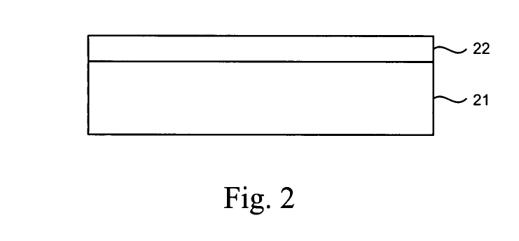

Referring to FIGS. 1 and 2, at 11, a ceramic substrate 21 is provided. The ceramic substrate 21 is made of aluminum oxide. The thickness of the substrate 21 is about 0.1 to 1.0 mm. A titanium-based film 22 is coated on the ceramic substrate 21. The thickness of the titanium-based film 22 is about 1000 to 5000 angstroms. The titanium-based film 22 is used both as a back contact and a seed layer. The titanium-based film 22 is made of TiSi₂, TiN, TiC, TiB₂ or TiCₓN_{y}.

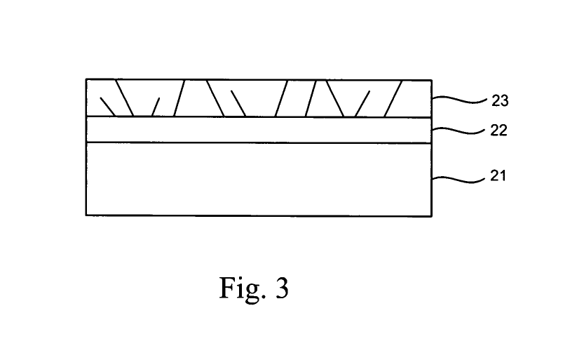

Referring to FIGS. 1 and 3, at 12, in an atmospheric pressure chemical vapor deposition (“APCVD”) device, at about 900 to 1000 degrees Celsius, for about 5 minutes, dichlorosilane and diborane exchange silicon atoms and boron atoms, thus causing the epitaxial growth of a back surface field (“BSF”) layer 23 on the titanium-based film 22. This exchange is called “inter-doping.” The concentration of the boron atoms in the BSF layer 23 is about 10¹⁸ #/mm³.

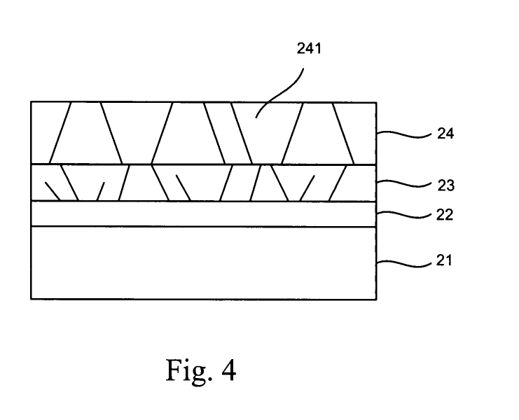

Referring to FIGS. 1 and 4, at 13, at higher than 1000 degrees Celsius, for about 30 minutes, the dichlorosilane and the diborane exchange silicon atoms and boron atoms, thus causing the epitaxial growth of a light-soaking layer 24 on the BSF layer 23, which is used as a core layer. The rate of the epitaxial growth is about 0.5 micrometer/minute. The thickness of the light-soaking layer 24 is about 1 to 15 micrometers. The size of silicon crystals 241 in the light-soaking layer 24 is about 10 micrometers. The concentration of the boron atoms in the light-soaking layer 24 is about 10¹⁶ to 10¹⁷ #/mm³.

As discussed above, the atmospheric pressure chemical vapor deposition process is conducted at higher than 900 degrees Celsius. The ceramic substrate 21 is made of aluminum oxide. The titanium-based layer 22 is used both as the back contact and the seed layer. Therefore, the rate of the epitaxial growth of the multi-crystalline silicon film is higher than 0.5 micrometer/minute, and the size of the silicon crystals is larger than 10 micrometers. Moreover, as multi-crystalline silicon exhibits high electron-hole mobility, large electron-hole diffusion length and long electron-hole recombination, the solar cell made according to the present invention exhibits a high epitaxial growth rate, excellent crystal quality, a high photoelectrical conversion efficiency and stable light-soaking. In addition, the cost of equipment is low, and the process simple.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A method for making a multi-crystalline silicon film of a solar cell, the method comprising the steps of:
providing a ceramic substrate;
coating a titanium-based film on the ceramic substrate;
coating a back surface field layer on the titanium-based film via providing dichlorosilane and diborane in an atmospheric pressure chemical vapor deposition process at a first temperature; and
coating a light-soaking layer on the back surface field layer via providing dichlorosilane and diborane in the atmospheric pressure chemical vapor deposition process at a second temperature higher than the first temperature.

2. The method according to claim 1, wherein the thickness of the ceramic substrate is about 0.1 to 1.0 mm.

3. The method according to claim 1, wherein the titanium-based film is made of a material selected from a group consisting of TiSi₂, TiN, TiC, TiB₂ and TiCₓN_{y}.

4. The method according to claim 1, wherein the thickness of the titanium-based film is about 1000 to 5000 angstroms.

5. The method according to claim 1, wherein the titanium-based film is used both as a back contact and a seed layer.

6. The method according to claim 1, wherein the first temperature is about 900 to 1000 degrees Celsius.

7. The method according to claim 1, wherein the rate of the epitaxial growth rate of the light-soaking layer is higher than about 0.5 micrometer/minute.

8. The method according to claim 1, wherein the thickness of the light-soaking layer is about 1 to 15 micrometers.

9. The method according to claim 1, wherein the size of silicon crystals in the light-soaking layer is larger than 10 micrometers.
